(19) United States
(12) Patent Application Publication
(10) Pub. No.: US 2002/0114880 A1
(43) Pub. Date: Aug. 22, 2002

(54) Coating of optical elements, in particular for use with ultraviolet light

(75) Inventors: Joerg Dreistein, Aalen (DE); Bernhard Weigl, Steinheim (DE)

Correspondence Address: SUGHRUE MION, PLLC, 2100 Pennsylvania Avenue, NW, Washington, DC, 20037-3213, US

(73) Assignee: CARL ZEISS SEMICONDUCTOR MANUFACTURING TECHNOLOGIES AG

(21) Appl. No.: 10/036,359

(22) Filed: Jan. 7, 2002

(30) Foreign Application Priority Data
Jan. 5, 2001 (DE) 10101014.1

(51) Int. Cl. B05D 5/06; C23C 16/00; C23F 1/00

(52) U.S. Cl. 427/8; 427/162; 156/345.31; 118/719

(57) ABSTRACT

In a method for coating optical elements for systems working with ultraviolet light, the coating process is performed in the evacuable working chamber of a coating system. At least one lock system is provided, equipped with a lock chamber that can be evacuated and, if desired, separated from the working chamber or connected to the working chamber in order to introduce optical elements. After the optical elements are moved into the lock chamber, different treatment steps may be performed there on the elements that were, or will be, coated. The treatment may include in particular cleansing with ultraviolet light, controlled heating or cooling, and/or measurement of at least one optical property of the optical elements. Using the lock chambers for the pre-treatment and post-treatment of optical elements immediately before or after a coating process permits improved control of the coating process and production of elements of highest quality with minimal total processing time.

The following disclosure is based on German Patent Application No. 101 01 014.1 filed on Jan. 5, 2001, which is incorporated into this application by reference.

### BACKGROUND OF THE INVENTION

1. Field of the Invention

This invention relates generally to a method for coating optical elements in a working chamber of a coating system, in particular to the coating of optical elements for systems using ultraviolet light, as well as to devices for performing the method.

2. Description of the Related Art

In many areas, there is increased demand for high-performance optical elements, such as lenses, mirrors, prisms, and the like, that have optical properties, such as transmittancy, reflectivity, absorption factor, and other properties (laser resistance, for example) that are optimized for the use with ultraviolet light. Light of this wavelength range is used, for example, for microlithography systems to produce highly integrated semiconductor devices using wafer steppers or wafer scanners. In this process, a light source illuminates a structured mask (reticle) through an optical illumination system. With the help of an optical projection system, the image of the mask is projected onto the element to be structured, for example a semiconductor wafer coated with a photo resist. As it is known that the fineness of the structures that can be achieved with this process increases with shorter wavelengths of the light used, wavelengths of the deep ultraviolet range have been increasingly used over the last years instead of the wavelengths available from mercury lamps (e.g., the g line at 436 nm and the i line at 368 nm). Suitable light sources are the KrF excimer lasers with a wavelength of 248 nm, ArF excimer lasers with a wavelength of 193 nm, and F2 lasers with a wavelength of 157 nm. The use of even shorter wavelengths up to the range of soft X-ray radiation is an aim for the future.

To achieve a certain functionality of an optical component, it is often advantageous or necessary to coat one or more surfaces with an optically effective thin coating in one or more layers. The typical coating thicknesses of the individual layers of a coating are often in the order of fractions of the light wavelength used. Accordingly, coatings in multiple layers often have a total coating thickness of less than 500 nm or 300 nm.

The production of thin coatings has increased demands with respect to the quality of the coating process, in particular to avoid contamination of the layers and of the surfaces to be coated. Even the smallest contaminations can make a coating, and thus the coated component, unfit for the intended use so that rejection of the element or time and cost consuming reworking is necessary. Coating must therefore generally take place in a high vacuum or ultrahigh vacuum. The systems necessary for this are expensive and may slow down the entire process because of long pump times to achieve the work pressure.

Other procedures are known to reduce contamination of the surfaces of coated optical elements after their final treatment. When polishing the surface, for example, possibly remaining treatment residues are cleaned chemically in an ultra circuit in a suitable watery solution. The cleaned elements are then washed in a final bath of ultra-purified water and dried before they are built in the working chamber of the intended coating system as soon as possible. Another known process is cleaning the built-in elements inside the already evacuated working chamber of the coating system using a glow discharge before the coating process begins.

Before and after the coating process, the optical properties of the coated elements are usually measured, for example spectroscopically. This is done to permit qualifying the components for their later use and drawing conclusions about the process and about possible improvement of the coating process. Generally, the post-cleansing is also performed wet chemically.

It has been shown that, even with most meticulous execution of the individual steps of the procedure (pre-treatment, coating, after-treatment), the described procedure does not always fulfill the high demands with respect to quality of optical components for ultraviolet light systems or does so only with very high effort. This causes increased rejection rates and thus increases the price of usable optical elements. The total process is also very time consuming.

Accordingly, this invention is based on an object of providing a method and suitable equipment that support coatings on an optimally prepared surface and/or better control of the coating process for coating optical components, in particular components for the use with ultraviolet light in order to lower the rejection rate and the cost of usable optical elements. It is a further, related object to shorten the overall process, including the coating process.

### SUMMARY OF THE INVENTION

These and other objects are solved, according to one formulation of the invention, by a method that includes the following steps:

providing at least one lock system with at least one evacuable lock chamber that may be separated from, or connected to, the working chamber of the coating device;

arranging or positioning at least one optical element inside the lock chamber;

treating the optical element inside the lock chamber;

equalizing the atmospheres of the working chamber and the lock chamber; and

transporting the optical elements between lock chamber and working chamber under exclusion of the environmental atmosphere.

In the inventive method or procedure that is intended in particular for coating optical elements of the type previously mentioned, the coating process takes place in a working chamber of a coating system which may be separated from the environmental atmosphere and evacuated. This may be a vapor deposition system for physical vapor deposition (PVD), for example. The procedure is also suitable for other vacuum processes, for example chemical vapor deposition (CVD) or embodiment procedures (e.g. LPCVD or PICVD) or sputtering.

The order of sequence of the method steps may vary depending on the progress of the procedure and individual steps may be repeated in the total process. For example, the elements may undergo a pre-treatment in the lock chamber before they are moved from the lock chamber to the working chamber under exclusion of the environmental atmosphere. In this case, the lock system may also be called a supply or entry lock.

After the coating process is finished, the optical elements may be transferred from the working chamber to the lock chamber under exclusion of the environmental atmosphere. In the lock chamber, a post-treatment of the optical elements may be performed. In this case, the lock system may also be called an exit or removal lock. One lock system may serve as a supply lock as well as a removal lock. However, it is also possible, for example for an in-line arrangement, to provide separate supply and removal locks.

One or more lock systems may also be permanently attached to the coating system. For example, the casing of a lock system can be welded vacuum-tight to the casing of a coating system where the openings of the casings meet. It is also possible to provide separate or removable lock systems that can be docked vacuum-tight with, or removed from, the coating system as needed. Likewise, it is possible for example to perform the treatment of the substrate inside the lock chamber before the lock system is docked with the coating system or after it is removed. It is thus possible to assign a coating system one or more “satellites” created by the lock system in which pre-treatment or post-treatment steps of the component that was or will be coated are performed while the coating system itself is already being prepared or used for a new coating job. With this procedure, considerable time savings may be achieved, in particular in the case of serial production.

Using lock systems for supplying and unloading the working chamber of the coating system also has advantages as far as the purity or the speed of the coating process is concerned because complete ventilation of the working chamber can be avoided. This is how contamination of the coating chamber can be largely avoided. Furthermore, the pressure in the coating chamber can go back to the low values necessary for the process more quickly when using a lock system to supply or remove the objects to be coated. This way, the cleaning intervals of the cryogenic pump, which are the preferred pump type because of their high pump capacity, can be considerably lengthened, minimizing down times due to maintenance work. This too increases productivity and decreases cost.

Locks are also known to be used in many fields of application as pre-chambers of gas-tight rooms and/or rooms at risk of contamination. They are used as a transition chamber, for example between an evacuable working chamber or a working chamber under certain atmospheric conditions and the environment. Often they also contain the supply or handling systems for transporting the items to be treated between lock chamber and working chamber. A lock system for transporting spectacle lenses into the working chamber of a coating device is known from the international patent application WO 9213114. The lock does not have any function other than equalizing the atmospheres between working chamber and lock chamber and transporting the still uncoated spectacle lenses to the coating chamber.

This invention however proposes treatment of the optical elements inside the lock chamber that go beyond these functions of transport, equalization of the atmospheres, and mere temperature measurement if applicable. A “treatment” for the purpose of this application includes in particular affecting the object to be coated or interacting with this object, attempting to change and/or measure the state or the properties of the object to be coated, in particular measuring its optical properties.

One preferred embodiment proposes cleaning the objects inside the lock chamber as part of the treatment, which can be done in particular using irradiation with ultraviolet light of suitable wavelength and intensity. The UV cleansing can be performed contact-free avoiding the risk of mechanically damaging the elements. The cleansing effect can be supported by evacuating the lock chamber during the cleansing process and/or rinsing it with gas so that removed contamination particles can be taken out of the lock chamber. This can reduce the re-contamination to a minimum.

Another method of ultraviolet cleansing is characterized in that before and/or during the cleansing process, the atmosphere of the lock chamber is enriched with a processing gas, e.g., with oxygen of suitable partial pressure. In combination with the entering UV radiation, ozonization and/or radicalization of the lock chamber atmosphere can thus be achieved. The surprising improvement of the cleansing effect by forming ozone and/or free radicals in this gas-supported UV cleansing can possibly be explained by the fact that the activated molecules prefer to react with carbon compounds under formation of carbon oxides, e.g. CO or CO₂. Due to their reduced reactivity, these oxides cause lower levels of re-contamination of the cleaned surface.

Cleansing, in particular using ultraviolet light, can be of advantage during different stages of the total process. In particular, the elements' surfaces may be cleansed before coating them. This pre-cleansing can be especially positive for the adhesion between the substrate and the coating. In addition, trapping of contaminations between the substrate and the coating layer can be largely avoided. It is also possible to perform an intermediate cleansing process between two coating steps when applying more than one coating. To do so, the element, which has already had one or more coatings applied to it, can be transported from the working chamber to the lock chamber, where it can be cleaned with UV light, for example, and moved back into the working chamber for the next coating. If needed, the intermediate cleansing process can be performed every time one individual coating of a multi-layer coating is applied. Instead of, or in addition to, the cleansing, other treatment steps, such as measurements, may be performed between the individual coating steps.

Post-cleansing the coated element in the lock chamber also has special advantages. It has been shown in experiments that post-cleansing generally is the more effective the shorter the time between finishing the coating and performing the post-cleansing. Post-cleansing is especially useful for coating processes where the elements to be coated must be turned in order to coat surfaces in different orientations. In this case, it may happen that a coated surface is located on a side turned away from the coating material source and therefore “sees” the background of the device. This can cause accumulation of deposits, which often causes absorption of the previously coated surfaces on the element after it is completely coated. Obviously, intermediate cleansing can also be used to remove contaminations that are created this way. With the possibility of performing the surface cleaning of the substrate that was, or will be, coated in a lock chamber that is separate from the coating chamber and that can be sealed, a cleansing device inside the coating chamber is unnecessary. This means that, for the same system size and for a reduced total surface of the inner surfaces of the coating chamber, more room is available for objects to be coated. Furthermore, contaminations of the inside of the working chamber can be avoided unlike in traditional procedures with cleansing inside the coating chamber, where such contaminations are inevitable.

In order to ensure a well controlled process with reproducible results of high quality, it is imperative to measure the properties of the objects that are the result of the coating by using suitable metrology. The actual properties can then be compared to the desired properties. This metrological qualification is necessary so that subsequent treatment steps are only performed on products that are within the given tolerance range. Furthermore, the measurement results, such as absorption behavior, transmission behavior, reflection behavior, or other properties, permit drawing conclusions on possible weaknesses in the coating process. This knowledge is the condition for systematic improvement of the quality of the coating processes. Only with a measurement before the coating, the measured result can be analyzed reliably.

According to the preferred embodiments, the treatment that can be performed in the lock chamber includes measuring at least one property of the objects inside the lock chamber. Instead of, or in addition to, optical properties, the temperature of the objects may also be determined, for example. Integrating the metrology in a lock system permits virtually instantaneous success control of the vapor deposition process. This way it is possible to make a reliable distinction between errors or weaknesses of the coating process and weaknesses or errors of subsequent processing steps. This is a considerable advantage over known procedures where the layer qualification often takes place a long time after the coating is finished. When an error occurs, it is not clear whether an artefact of the vapor deposition process or an artefact of subsequent re-contamination was measured.

Furthermore, measurements inside the lock chamber permit measuring under a controlled atmosphere, for example in a vacuum or a suitable inert gas, so that negative impacts of the environmental atmosphere on the measurements, e.g. by absorption of the measuring light, may be avoided.

The treatment that can be performed inside a lock chamber can also include a controlled change of temperature of the objects inside the lock chamber. The objects may be heated to a given temperature with a controllable heating rate, kept at a given temperature, and/or cooled with a controlled cooling rate. Heating the temperatures considerable above room temperature, for example to over 100° C., can support the effects of the ultraviolet cleansing. It has been shown, for example, that the intensity of the ultraviolet light for achieving a given cleansing power may be reduced if the object to be cleaned is heated. When using gas to aid the cleansing, however, it must be observed that the gas streaming onto the heated objects should also be heated to a temperature comparable to the object temperature in order to avoid tensions due to heat differences and, consequently, crack formations on the surface of the substrate. This problem occurs particularly with crystalline substrate materials, such as calcium fluoride or barium fluoride, which are the materials of choice for optical systems using this wavelength range because of their favorable absorptions properties for ultraviolet light.

Heating of the substrates can be done, for example, with one or more radiating heating elements that can be positioned in a suitable place inside the lock chamber. Instead, or in addition, heating can be provided by a hot gas. A combination of radiation and convection heating is also possible. For this purpose, the lock chamber may be filled with a gas that serves as a heat convection material between the radiating heating elements and the object to be coated. The heat supply and removal to and from the objects with a suitable gas atmosphere can be done faster than in a vacuum, achieving time savings in the total process. Heating supported by gas also permits especially uniform heating or cooling, which is particularly useful for heat tension sensitive materials, such as fluoride single crystals.

As mentioned in the beginning, this invention has special advantages in the coating of optical elements intended for the use with ultraviolet light. However, this invention is not restricted to such coating objects, but can be advantageous for coating objects of any kind, in particular if quick processing is desired with a high coating quality that can be reproduced well. The term “optical element” may thus represent coating objects of any suitable kind.

This invention also concerns elements where at least one surface was coated using the procedure of this invention and more complex optical systems that are assembled using optical elements that were coated according to this invention.

This and other properties can be seen not only in the claims but also in the description and the drawings, wherein the individual characteristics may be used either alone or in sub-combinations as an embodiment of the invention and in other areas and may individually represent advantageous and patentable embodiments.

Embodiments of the invention are shown in the drawings and explained in detail in the following.

### BRIEF DESCRIPTION OF THE DRAWINGS

FIG. 1 is a schematic representation of a vapor deposition system with a single lock system, used as a supply and removal lock, according to one embodiment of the invention, and

FIG. 2 is a schematic representation of a different embodiment of a vapor deposition system with a supply lock and a separate removal lock.

### DETAILED DESCRIPTION OF PREFERRED EMBODIMENTS

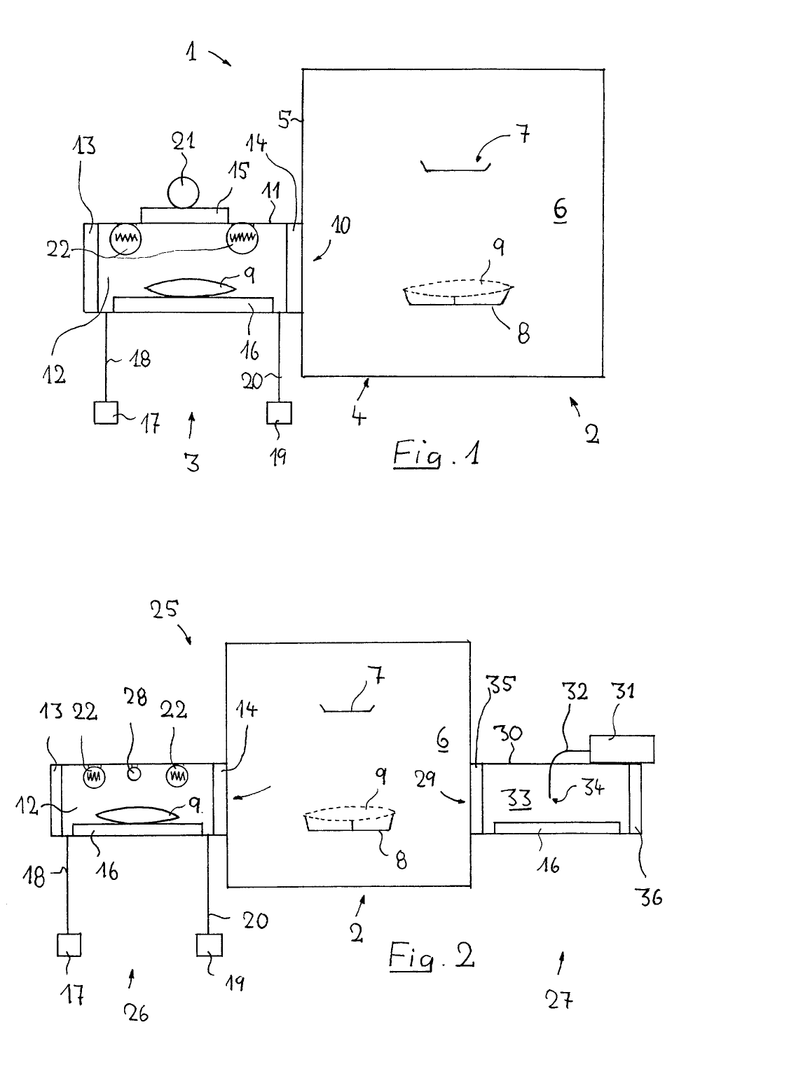

FIG. 1 schematically shows a coating system 1 that is specially optimized for the coating of optical elements used in optical instruments for the use with ultraviolet light. The optical elements may be lenses, prisms, mirrors, beam splitters, polarizers, filter, or other elements that are intended for producing illumination or projection lenses or other functional units of UV microlithography devices, such as lasers.

The coating system 1 contains all essential components of a vapor deposition system 2 and a lock system 3, which is connected vacuum-tight to the vapor deposition system. The vapor deposition system 2 has a recipient 4 designed for ultrahigh vacuum with a thick-walled stainless steel casing 5 that includes a working chamber 6 of the vapor deposition system. A cryogenic pump that is not shown is used for evacuating the high-volume working chamber. The suction side of the pump is connected to the working chamber 6. In the upper part of the working chamber, there is an electrically controlled vapor deposition source 7, which is directed at an object holder 8 below.

The casing wall 5 is equipped with a casing wall opening 10 for supplying and emptying the working chamber 6. The opening can be closed vacuum-tight. In the area of the casing wall opening on the outer wall of the recipient casing 5, a removable lock system 3 with a box-shaped stainless steel casing 11 is docked vacuum-tight with the opening. The docking devices, which are not described and may be shaped like a vacuum flange, permit a rigid, high vacuum-tight, releasable connection between the casings 5 and 11 of the vapor deposition device 2 and the lock system 3. The lock chamber 12 enclosed by casing 11 can be sealed vacuum-tight on its narrow sides with the lock devices 13, 14. It is accessible if at least one of the lock devices is opened. The lock system with its lock devices 13, 14 is dimensioned such that the largest objects that can be coated in the vapor deposition system 2 may be moved through the lock system without risk of being damaged when the lock devices are opened. On at least one casing side, for example on the top of the casing 11, there is a vacuum-tight window 15 in one of the casing wall opening that is made of a material transparent to ultraviolet light, such as quartz glass.

Inside the lock casing 11, an electrically powered, mechanical manipulation device 16 is built in (shown schematically). This device is used to move objects into the lock system and hold them in place inside the lock system at adjustable positions and orientations. In particularly, it is designed to transport objects to be coated to the working chamber 6 and/or hand them over to another manipulation device there while the first lock device 13 is closed and the second lock device 14 is open. It can also be used to transfer objects from the vapor deposition chamber 6 to the lock chamber 12. For example, the manipulation device can contain at least one conveyer belt and/or at least one rotatable and/or shiftable magazine or the like. In the example, it is carrying a lens 9 made of calcium fluoride.

The atmosphere inside the lock chamber 12 may be controlled by devices assigned to the lock chamber. These include a vacuum pump 17 with a suction line 18 leading to the lock chamber 12, which is designed such that the inside of the lock chamber may be evacuated to a residual pressure that is essentially equal to the working pressure inside the working chamber 6. In addition, a gas source 19 is provided with a gas line 20 leading to the lock chamber. With one or more such gas sources, the lock chamber can filled in a controlled manner with gases that have the desired properties, such as inert gas, nitrogen, oxygen, and the like.

A special feature of this invention is that the lock system is equipped not only with the mentioned means for moving and positioning of the objects to be locked and the devices for establishing a proper lock atmosphere, but also with additional devices that allow treatment of these objects inside the lock chamber. This way, the lock chamber 11 may be used as an additional working chamber of the total coating system where the objects to be coated may be optimally prepared for the coating process or undergo post-treatment after the coating under exclusion of the environmental atmosphere.

Particularly advantageous is a cleaning device including at least one ultraviolet light source 21 as an essential constituent. In an embodiment according to FIG. 1, this light source is positioned outside the lock chamber 12 in the area of the window 15 in such a manner that the emitted UV radiation can affect the surfaces of objects 9 inside the lock chamber facing the light source with high efficiency. The UV source 21, which can be a UV light tube for example, can be shielded on the outside by a light-impermeable shield (not shown).

There is also the possibility of heating the objects inside the lock chamber to adjustable temperatures. For this purpose, two radiating heaters 22 are provided. The heaters are positioned on the top wall of the casing 11 such that their heat radiation essentially affects the same surfaces that are subjected to the UV radiation of the light source 21 if applicable.

The control of the handling and treatment devices and the lock devices can be done either manually or computer-aided with a common control unit (not shown).

A coating system of the kind described as an example here permits coating optical components or other objects according to the following procedure.

At the beginning of a coating cycle, the working chamber 6 of the vapor deposition system is evacuated to a high vacuum of e.g. under 10⁻⁶ mbar and at least the second lock device 14 is closed. If the first lock device 13 is closed, it is opened to hand over one or more objects to the manipulation device 16. After this loading process, the first lock device is closed, sealing the lock chamber gas-tight. By turning on the ultraviolet light source 21, contaminations, in particular organic contaminations, can be cleaned on the surfaces of the lens 9 that face the light source. This process may take place in an atmosphere similar to the environmental atmosphere. However, it is possible to evacuate the lock chamber with the pump 17 before or during the UV irradiation. The evacuation during the irradiation may be advantageous to pump out contamination particles immediately after they are removed from the object in order to avoid re-contamination of the object surface. It is also possible to perform a gas exchange in the lock chamber by pumping it out while letting a suitable gas flow into the chamber from the gas source 18 during or after the evacuation. In some cases, a gas injection with oxygen or another processing gas with or without oxygen has given especially good results. This is possibly due to the fact that the ozone molecules and/or radicals formed under UV light radiation have an advantageous getter effect on the released contaminations, in particular on contaminations containing carbon atoms. They may also mechanically affect the surface to be cleaned.

The cleansing may be supported by heating the object 9. For this purpose the radiating heaters 22 are turned on before or during the UV irradiation. Mere radiation heating is unproblematic for objects resistant to heating tensions, such as objects made of silicon glass. However, in other objects, in particular in fluoride single crystals such as calcium fluoride, the temperature gradients between object surface and the inside of the object caused by the heat radiation may create thermally induced cracks. This may be avoided by using gas to support the heating. For this purpose, a hot gas may be injected into the lock chamber for example. Alternatively, the lock chamber can be filled with a gas as a heat convection medium before or while the radiating heaters 22 are turned on. This permits heating the object gently and uniformly. A processing gas may also be used as a hot gas, serving two functions, heating and cleaning the object.

If needed, the cleaning success may be measured spectroscopically or by other means after the cleaning, as will be explained in detail in connection with FIG. 2. After the pre-treatment is finished, the atmospheres of lock chamber 12 and working chamber 6 will be equalized by evacuating the lock chamber to the working chamber pressure. If needed, the measurement mentioned above can be performed at that time, i.e., in the vacuum. Then the second lock device 14 is opened, the object is positioned for the vapor deposition in the working chamber 6, and the second lock device is closed again starting the working interval of the vapor deposition system.

After this pre-treatment, it is not necessary to perform additional pre-treatment during the working interval in the working chamber 6. In particular, cleaning and/or heating the object to be coated is not needed. The lock system also makes it unnecessary for the working chamber 6 to be ventilated when the object to be coated is inserted. The working chamber can thus remain permanently evacuated, avoiding contaminations and drastically reducing the necessary pumping times. Since the object is preheated in the lock chamber it is also no longer necessary to provide heating devices in the working chamber and perform heating processes there. This avoids strong temperature changes in the processing chamber 6, facilitating stable processes.

After the vapor deposition, which can be performed with known procedures, the second lock device 14 is opened again, the object is moved to the lock chamber 12, and the lock door 14 is closed again. If the lock system is equipped accordingly, a qualification of the coated object is also possible at this stage, for example with spectrometric measurement of the reflectivity, the transmittance, and/or the absorption or the like. The lock chamber 12 can then be flooded with an inert gas or with air until a pressure is reached that permits easy opening of the first lock device 13. Then the object is removed and a new object may be locked.

The coating system 25 in FIG. 2 is equipped for in-line operation. This means that the supply of the device is done through a supply lock system 26 corresponding to the lock system 3, while the objects are removed through a separate removal lock system 27 on the opposite side. The build-up of the supply lock system 26 essentially corresponds to the lock system 3 of FIG. 1, which is why the same reference marks are used for the corresponding parts. One difference from the embodiment according to FIG. 1 is that the UV light source 28 is located inside the lock chamber between the radiating heaters 22 so that the window 15 is unnecessary. In this case, the UV light source must be suitable for use in a high vacuum atmosphere.

The removal lock system 27, which ideally is fastened permanently or removably in the area of a casing opening 29 opposite of the casing opening 9, is designed as a measurement lock system. It permits measuring parameters that are significant for the qualification of the coated objects, such as reflectivity, transmittance, absorption factor, or the like, immediately after the coating under vacuum without having to subject the object to the environmental atmosphere in the meantime. For this purpose, a spectrometer 31 is provided as a measuring system on the top of the casing 30. From the spectrometer, a light guide 32 used to guide the beam leads into the inside of the lock chamber. The exit or entry end 34 of the light guide is positioned such that light can radiate the surface of the object to be qualified. The reflected or transmitted light can be intercepted by a sensor, e.g., through a light guide, and sent back to the spectrometer. If needed, UV cleansing after the coating process may be provided in the lock (not shown in FIG. 2).

The loading of the working chamber through the loading lock, including cleansing and/or heating the object to be coated, can be performed analog to the procedure described in FIG. 1. In this case, however, unlike in the other procedure, the lock system 26 can be prepared for locking one or more subsequent objects after the object to be coated is transferred into the working chamber 6 and the second lock device 14 is closed. In the meantime, the vapor deposition may be performed in the working chamber. By providing at least two separate lock systems so that previously loaded objects can be locked in or out while the actual vapor deposition is taking place, considerable time savings may be achieved.

When the vapor deposition of an object in the working chamber 6 is finished, the third lock device 35 can be opened and the object can be moved to the lock chamber 33 that was previously evacuated to the system pressure. After the third lock device is closed, the working chamber can immediately be loaded through the loading lock 26. The inside 33 of the exit lock 27 now serves as an evacuable measuring chamber where the result of the vapor deposition process can be verified by using the spectrometer 31 and/or other suitable measuring instruments. The results of this measurement permit reliable conclusions about the quality of the vapor deposition because it can be ruled out that occurring errors are the result of effects of the environmental atmosphere on the finished coating after the vapor deposition has finished. After the measurement has finished, the inside of the lock 33 can be flooded with an inert gas or with air to bring the inside 33 to a pressure comparable to the environmental pressure, which is needed to open the fourth lock device 36. After this lock device is opened, the object may be removed and the lock closed again.

From the build-up and procedure variations given as examples here, it becomes clear that the lock technology made possible by this invention may considerably reduce evacuation times and pumping processes in the processing chamber 6 for coating systems for optical parts or the like. By minimizing the pumping times, more coating objects may be processed per unit time in the generally very expensive coating system than in comparable systems without lock technology. In addition, temperature changes inside the working chamber may be reduced to a minimum, permitting more stable vapor deposition processes and improving the reproducibility of the produced coatings. Lastly, the qualification shortly after the process with the metrology integrated into the lock system allows for a more precise control over the coating process and thus permits the optimization of critical processing parameters for achieving highest coating qualities.

The above description of the preferred embodiments has been given by way of example. From the disclosure given, those skilled in the art will not only understand the present invention and its attendant advantages, but will also find apparent various changes and modifications to the structures and methods disclosed. It is sought, therefore, to cover all changes and modifications as fall within the spirit and scope of the invention, as defined by the appended claims, and equivalents thereof.

What is claimed is:

1. A method for coating optical elements, in particular those optical elements for optical systems using ultraviolet light, in a working chamber of a coating device, the method comprising:
providing at least one lock system with at least one evacuable lock chamber that may be separated from, or connected to, the working chamber;
positioning at least one optical element in the lock chamber;
treating the optical element inside the lock chamber;
equalizing the atmospheres of the working chamber and the lock chamber;
transporting the optical element between lock chamber and working chamber under exclusion of the environmental atmosphere.

2. A method according to claim 1, wherein the treating step comprises cleansing of the optical element in the lock chamber, the cleansing step comprising irradiation of the optical element with ultraviolet light.

3. A method according to claim 2, wherein an evacuation of the lock chamber is performed during the cleansing.

4. A method according to claim 2, wherein before and/or during the UV cleansing the atmosphere in the lock chamber is enriched with a processing gas, such as oxygen.

5. A method according to claim 1, wherein the treating step comprises pre-cleansing of at least one surface of an optical element that is to be coated before the coating takes place.

6. A method according to claim 1, wherein the step of coating optical elements includes depositioning multiple coatings using at least two subsequent coating steps, wherein at least one treatment step performed inside the lock chamber is performed between two subsequent coating steps performed in the working chamber.

7. A method according to claim 1, wherein the treating step comprises post-cleansing of finished, coated optical elements in the lock chamber.

8. A method according to claim 1, wherein the treating step comprises measuring at least one optical property of the optical element inside the lock chamber.

9. A method according to claim 8, wherein the step of measuring includes at least one of measuring the transmittancy, the reflectivity and the absorption factor of the optical element.

10. A method according to claim 8, wherein the measuring step performed inside the lock chamber is performed in a lock chamber atmosphere different from the environmental atmosphere.

11. A method according to claim 10, wherein the measuring step performed inside the lock chamber is performed in a vacuum.

12. A method according to claim 1, wherein the treating step comprises controlling the temperature of the optical element in the lock chamber.

13. A method according to claim 12, wherein the step of controlling the temperature of the optical element includes at least one of changing the temperature of the optical element with a controlled rate of temperature change and maintaining the temperature of the optical element at a predetermined temperature.

14. A method according to claim 12, wherein the step of controlling the temperature of the optical element includes introducing a gas into the lock chamber for at least one of performing and supporting the step of controlling the temperature of the optical element by action of the gas introduced into the lock chamber.

15. A method according to claim 14, wherein the gas introduced into the lock chamber is a hot gas with a temperature above the temperature of the environment, whereby the temperature of the optical element is increased above the temperature of the environment at least partially by contacting the optical element with the hot gas.

16. A method according to claim 12, wherein the step of controlling the temperature of the optical element comprises radiating heat radiation onto the optical element.

17. A method according to claim 1, wherein a plurality of optical elements is coated in one process, the process being divided into several processing intervals, wherein during one processing interval at least one optical element is arranged inside a closed working chamber for coating and at least one other optical element is arranged in a lock chamber assigned to the working chamber, wherein treating of the optical element inside the lock chamber is performed during other processing interval.

18. A lock system adapted for being connected in vacuum tight manner to a coating device, the coating device being equipped with at least one working chamber for coating optical elements, the lock system comprising:
a casing containing at least one evacuable lock chamber, the lock chamber being equipped with at least one access opening that can be either opened for introducing optical elements into the lock chamber or removal of optical elements out of the lock chamber;
at least one lock device for opening or closing the access opening; and
at least one treatment device assigned to the lock chamber for treating optical elements arranged in the lock chamber.

19. A lock system according to claim 18, wherein at least one treatment device is a cleansing device for at least one of contact-free and dry cleansing of at least one surface of an optical element arranged in the lock chamber.

20. A lock system according to claim 19, wherein the cleansing device is provided with at least one ultraviolet light source.

21. A lock system according to claim 19, wherein at least one vacuum tight window is incorporated into a casing wall of the casing of the lock system, the window being made of a material permeable for ultraviolet light and wherein at least one ultraviolet light source is located outside the lock chamber in the area of the ultraviolet light-permeable window so that optical elements inside the lock chamber may be irradiated with light from the ultraviolet light source through the window.

22. A lock system according to claim 18, wherein at least one gas supply line is provided to lead into the lock chamber, the gas supply line being adapted to be connected to an external gas source.

23. A lock system according to claim 18, wherein at least one suction line is provided to lead into the lock chamber, the suction line being connectable or connected to a vacuum pump.

24. A lock system according to claim 18, wherein at least one treatment device assigned to the lock chamber is a measuring device for measuring at least one property of at least one optical element arranged inside the lock chamber.

25. A lock system according to claim 24, wherein the measuring system is designed to measure at least one optical property of an optical element arranged in the lock chamber.

26. A lock system according to claim 18, wherein at least one heating device for heating optical elements inside the lock chamber is assigned to the lock system.

27. A lock system according to claim 26, wherein the heating device comprises at least one radiation heating element for heating optical elements inside the lock chamber using heat radiation.

28. A lock system according to claim 18, wherein at least one of at least one device for introducing hot gas into the lock chamber and at least one device for introducing processing gas with a set temperature into the lock chamber is assigned to the lock system.

29. A lock system according to claim 18, wherein the working chamber of a coating device is free from systems for at least one of cleansing and heating the optical elements to be coated in the working chamber.

30. A coating system for coating optical elements, the coating system comprising a coating device equipped with at least one working chamber for coating optical elements inside the working chamber, wherein the coating device is assigned at least one lock system, the lock system comprising:
a casing containing at least one evacuable lock chamber, the lock chamber being equipped with at least one access opening that can be either opened for introducing optical elements into the lock chamber or removal of optical elements out of the lock chamber;
at least one lock device for opening or closing the access opening;
and at least one treatment device assigned to the lock chamber for treating optical elements arranged in the lock chamber.

31. A coating system according to claim 30, wherein at least two lock systems are assigned to the coating system.

32. A coating system according to claim 31, wherein one lock system is designed as a supply lock system for introducing optical elements out of the supply lock system into the working chamber and another lock system is designed as an exit lock system for removing optical elements out of the working chamber through the exit lock system.

33. A coating system according to claim 30, wherein the coating device and the lock system are adjusted to each other such that the lock system can be connected to and is removable from the coating device, creating a vacuum tight connection between the lock chamber and the working chamber.

34. A method for coating optical elements, in particular those optical elements for optical systems using ultraviolet light, in a working chamber of a coating device, the method comprising:
providing at least one lock system with at least one evacuable lock chamber that may be separated from, or connected to, the working chamber;
positioning at least one optical element in the lock chamber;
treating the optical element inside the lock chamber, wherein the treating step comprises measuring at least one optical property of the optical element inside the lock chamber;
equalizing the atmospheres of the working chamber and the lock chamber;
transporting the optical element between the lock chamber and the working chamber under exclusion of the environmental atmosphere.

35. A coating system for coating optical elements, the coating system comprising a coating device equipped with at least one working chamber for coating optical elements inside the working chamber, wherein the coating device is assigned at least one lock system, the lock system comprising:
a casing containing at least one evacuable lock chamber, the lock chamber being equipped with at least one access opening that can be either opened for introducing optical elements into the lock chamber or removal of optical elements out of the lock chamber;
at least one lock device for opening or closing the access opening;
and at least one treatment device assigned to the lock chamber for treating optical elements arranged in the lock chamber, the treatment device comprising at least one measuring device for measuring at least one optical property of the optical element inside the lock chamber.
